(19) United States
(12) Patent Application Publication
(10) Pub. No.: US 2015/0291812 A1
(43) Pub. Date: Oct. 15, 2015

(54) Low Emissivity Glass Incorporating Phosphorescent Rare Earth Compounds

(71) Applicant: INTERMOLECULAR INC., San Jose, CA (US)

(72) Inventors: Abraham Anapolsky, San Jose, CA (US); Scott Jewhurst, Redwood City, CA (US); Daniel Schweigert, Fremont, CA (US)

(73) Assignee: INTERMOLECULAR, INC., San Jose, CA (US)

(21) Appl. No.: 14/250,210

(22) Filed: Apr. 10, 2014

(51) Int. Cl. C09D 5/32; C23C 16/515; C23C 16/513; C23C 28/04; C23C 16/42

(52) U.S. Cl. CPC C09D 5/32; C23C 28/042; C23C 16/42; C23C 16/513; C23C 16/515

(57) ABSTRACT

Methods, and coated panels fabricated from the methods, are disclosed to form multiple coatings, (e.g., one or more infrared reflective layers), with minimal color change before and after heat treatments. The optical properties of the coating (e.g. the transmissivity and the IR emissivity) are generally coupled. In some embodiments, silicate materials are doped with rare earth elements. These doped silicate materials are able to absorb ultra-violet (UV) photons and emit photons in the visible range. This allows the transmissivity to be at least partially decoupled from the IR emissivity of the coated panel, resulting in a larger range of performance.

### FIELD OF THE INVENTION

The present invention relates generally to films providing high transmittance and low emissivity, and more particularly to such films deposited on transparent substrates.

### BACKGROUND OF THE INVENTION

Sunlight control glasses are commonly used in applications such as building glass windows and vehicle windows, typically offering high visible transmission and low emissivity. High visible transmission can allow more sunlight to pass through the glass windows, thus being desirable in many window applications. Low emissivity can block infrared (IR) radiation to reduce undesirable interior heating.

In low emissivity glasses, IR radiation is mostly reflected with minimum absorption and emission, thus reducing the heat transferred to and from the low emissivity surface. Low emissivity, or low-e, panels are often formed by depositing a reflective layer (e.g., silver) onto a substrate, such as glass. The overall quality of the reflective layer, such as with respect to texturing and crystallographic orientation, is important for achieving the desired performance, such as high visible light transmission and low emissivity (i.e., high heat reflection). In order to provide adhesion, as well as protection, several other layers are typically formed both under and over the reflective layer. The various layers typically include dielectric layers, such as silicon nitride, tin oxide, and zinc oxide, to provide a barrier between the stack and both the substrate and the environment, as well as to act as optical fillers and function as anti-reflective coating layers to improve the optical characteristics of the panel.

Low-emissivity coatings can also be engineered to provide desired shading properties. When sunlight reaches a window, a portion can pass through the window, a portion can be reflected, and a portion can be absorbed, (which can increase the temperature of various parts of the window). A portion of the absorbed heat can radiate to the inside of the building, thus increasing the temperature of the air in the building. Thus, when sunlight is incident upon a glass window, in addition to lighting the interior of the building, the incident solar radiation can also pass through the window to increase the temperature of the building. Solar Heat Gain Coefficient (SHGC) is defined as the fractional amount of the solar energy that strikes a window that contributes to warming the building. Other terms can also be used, such as solar shading property or Light to Solar Gain (LSG), which is used to describe the relationship between lighting and heating from solar irradiation. Light to Solar Gain is defined as the ratio of visible light transmission to solar heat gain coefficient. In the hot weather, it is desirable to have high LSG glass. For example, commercial glass coatings are generally recommended to have LSG greater than 1.8.

There can be a tradeoff between having high visible transmittance and high light to solar gain. Transparent glass can provide high light transmittance but also high solar gain, (e.g., low light to solar gain). Dark glass can provide low solar gain, but also low light transmittance. Low emissivity coatings incorporating silver can provide significant improvements in terms of both visible light transmittance and light to solar gain properties. However, further improvement in light to solar gain is difficult; for example, low emissivity coatings having thicker silver layers, or having multiple silver layers, (e.g., double silver layer or triple silver layer), can reduce the solar heat gain, but at the expense of lower light transmission.

Another desired characteristic of the low-emissivity glass coatings is a color neutral property, (e.g., colorless glass). The glass coatings should not exhibit observable hues, (e.g., more red or blue than is desired).

Another desired characteristic of the low-emissivity glass coatings is temperature stability, (e.g., similar performance and appearance before and after heat treatment). Since glass can be tempered, (e.g., heating the glass to 600-700° C.), the appearance of the low-emissivity coatings can change significantly during the heat treatment process. To accommodate the tempering changes, low-emissivity coatings can be provided in a temperable version (e.g., heat treated) and a non-temperable version (non-heat treated). This is inconvenient in a manufacturing environment since two separate types of inventory must be maintained. The film stack of the temperable version can be designed to have properties matching those of the non-temperable version.

It would be desirable to provide low-emissivity coatings that can provide high visible transmittance, high light to solar gain, color neutral, and thermal stability for color and optical performance.

### SUMMARY OF THE DISCLOSURE

The following summary of the disclosure is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

In some embodiments, methods, and coated panels fabricated from the methods, are disclosed to include multiple coatings, (e.g., one or more infrared reflective layers), with minimal color change before and after heat treatments. The optical properties of the coating (e.g. the transmissivity and the IR emissivity) are generally coupled. In some embodiments, silicate materials are doped with rare earth elements. These doped silicate materials are able to absorb ultra-violet (UV) photons and emit photons in the visible range. This allows the transmissivity to be at least partially decoupled from the IR emissivity of the coated panel, resulting in a larger range of performance.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a schematic diagram for implementing combinatorial processing and evaluation.

FIG. 2 is a schematic diagram for illustrating various process sequences using combinatorial processing and evaluation.

FIG. 3 is a simplified schematic diagram illustrating an integrated high productivity combinatorial (HPC) system.

FIG. 4 illustrates a physical vapor deposition (PVD) system according to some embodiments.

FIG. 5 illustrates a low emissivity transparent panel 100 according to some embodiments.

FIGS. 6A-6B illustrate physical vapor deposition (PVD) systems according to some embodiments.

FIG. 7 illustrates an exemplary in-line deposition system according to some embodiments.

FIG. 8 illustrates a flow chart for forming coated layers according to some embodiments.

### DETAILED DESCRIPTION OF THE DISCLOSURE

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

Before various embodiments are described in detail, it is to be understood that unless otherwise indicated, this invention is not limited to specific layer compositions or surface treatments. It is also to be understood that the terminology used herein is for the purpose of describing particular embodiments only and is not intended to limit the scope of the present invention.

It must be noted that as used herein and in the claims, the singular forms “a,” “an,” and “the” include plural referents unless the context clearly dictates otherwise. Thus, for example, reference to “a layer” includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention. The term “about” generally refers to ±10% of a stated value.

The term “substrate” as used herein may refer to any workpiece on which formation or treatment of material layers is desired. Substrates may include, without limitation, float glass, low-iron glass, borosilicate glass, display glass, alkaline earth boro-aluminosilicate glass, fusion drawn glass, flexible glass, specialty glass for high temperature processing, polyimide, plastics, polyethylene terephthalate (PET), etc. for either applications requiring transparent or non-transparent substrate functionality.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

As used herein, a material (e.g. a dielectric material or an electrode material) will be considered to be “crystalline” if it exhibits greater than or equal to 30% crystallinity as measured by a technique such as x-ray diffraction (XRD).

The term “Solar Heat Gain Coefficient (SHGC)” is defined as the fractional amount of the solar energy that strikes a window that contributes to warming the building.

The term “Light to Solar Gain (LSG) is defined as the ratio of visible light transmission to solar heat gain coefficient.

As used herein, the notation “Ni—Ti—Nb—O” and “NiTiNbO” and NiTiNbOₓ” will be understood to be equivalent and will be used interchangeably and will be understood to include a material containing these elements in any ratio. Where a specific composition is discussed, the atomic concentrations (or ranges) will be provided. The notation is extendable to other materials and other elemental combinations discussed herein.

As used herein, the terms “film” and “layer” will be understood to represent a portion of a stack. They will be understood to cover both a single layer as well as a multilayered structure (i.e. a nanolaminate). As used herein, these terms will be used synonymously and will be considered equivalent.

As used herein, the phrase “site-isolated region” (SIR) will be understood to refer to two or more regions defined on a substrate that are separated from each other and used for the evaluation of different materials or process parameters. The SIRs can be formed using many different methods such as scribing, deposition through a shadow mask, deposition using isolated deposition heads, lithography, and the like. The present disclosure is not limited by the method used to form the SIRs.

As used herein, the phrase “rare earth element” will be understood to include the fifteen lanthanide elements (i.e. Ce, Pr, Nd, Pm, Sm, Eu, Gd, Tb, Dy, Ho, Er, Tm, Yb, Lu) as well as Sc and Y, as defined by the International Union of Pure and Applied Chemistry (IUPAC).

As used herein, the phrases “wavelength shifting material (or layer)” or “wavelength shifter material (or layer)” will be understood to be equivalent and will be used interchangeably. Further, they will be understood to refer to materials (or layers) that generally absorb photons of a higher frequency and emit photons with one or more lower frequencies.

The manufacture of low-e panels entails the integration and sequencing of many unit processing steps. As an example, low-e panel manufacturing typically includes a series of processing steps such as cleaning, surface preparation, deposition, patterning, etching, thermal annealing, and other related unit processing steps. The precise sequencing and integration of the unit processing steps enables the formation of functional coatings meeting desired performance metrics such as efficiency, transmissivity, and IR emissivity.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of low-e panels. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009, the entireties of which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005, the entireties of which are all herein incorporated by reference.

HPC processing techniques have been successfully adapted to wet chemical processing such as etching, texturing, polishing, cleaning, etc. HPC processing techniques have also been successfully adapted to deposition processes such as physical vapor deposition (PVD), atomic layer deposition (ALD), and chemical vapor deposition (CVD).

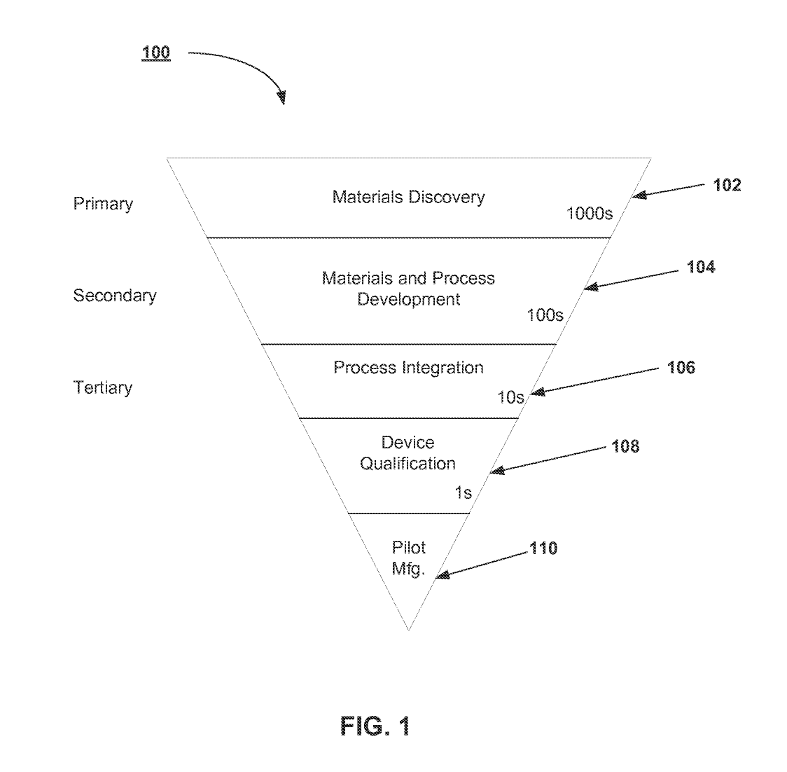

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to low-e panel qualification, 108. In low-e panel qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

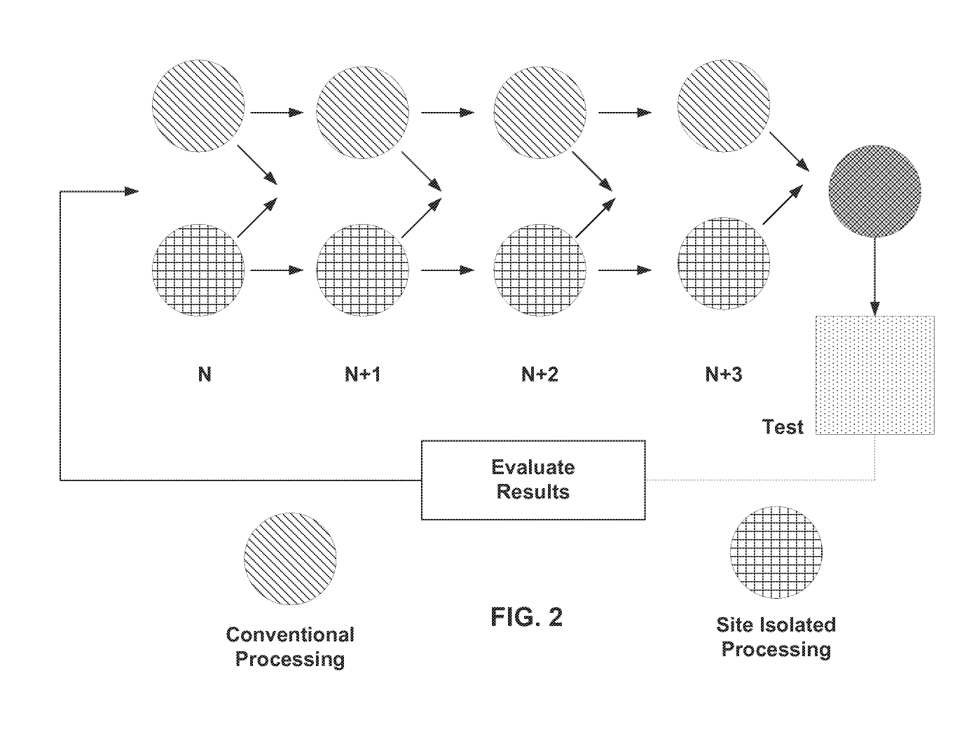

FIG. 2 is a simplified schematic diagram illustrating a general methodology for combinatorial process sequence integration that includes site isolated processing and/or conventional processing in accordance with some embodiments. In some embodiments, the substrate is initially processed using conventional process N. In some embodiments, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It will be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It will be appreciated that these process parameters are exemplary and not meant to be an exhaustive list as other process parameters commonly used in low-e panel manufacturing may be varied.

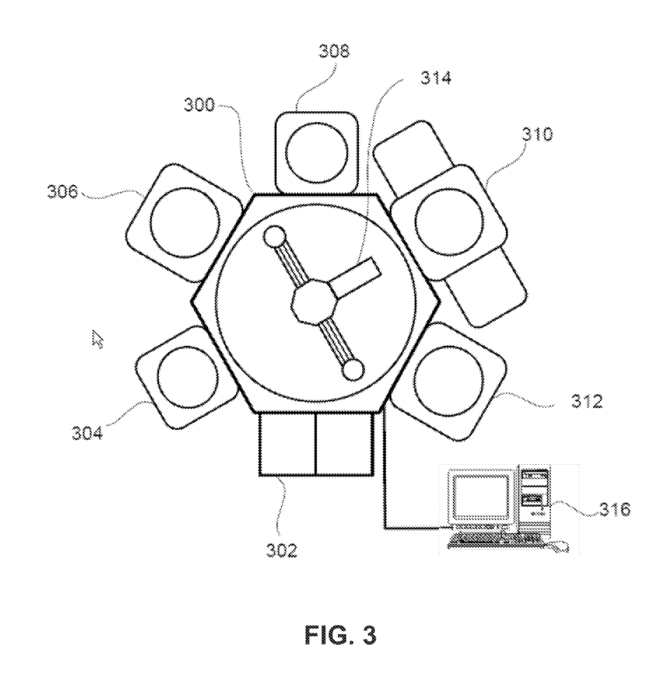

FIG. 3 is a simplified schematic diagram illustrating an integrated high productivity combinatorial (HPC) system in accordance with some embodiments. The HPC system includes a frame 300 supporting a plurality of processing modules. It will be appreciated that frame 300 may be a unitary frame in accordance with some embodiments. In some embodiments, the environment within frame 300 is controlled. A load lock 302 provides access into the plurality of modules of the HPC system. A robot 314 provides for the movement of substrates (and masks) between the modules and for the movement into and out of the load lock 302. Modules 304-312 may be any set of modules and preferably include one or more combinatorial modules. For example, module 304 may be an orientation/degassing module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, i.e., computing device 316, may control the processes of the HPC system. Further details of one possible HPC system are described in U.S. application Ser. Nos. 11/672,478 and 11/672,473, the entire disclosures of which are herein incorporated by reference. In a HPC system, a plurality of methods may be employed to deposit material upon a substrate employing combinatorial processes.

In some embodiments, a process chamber for combinatorial processing of a substrate is provided that includes one or more assemblies for sputtering material from targets (such as sputter guns); a power source coupled to the one or more sputter guns; a substrate support; a power source (e.g. RF, DC, pulsed DC, or the like) coupled to the substrate support; and a grounded shield comprising an aperture disposed between the substrate support and the one or more sputter guns to form a dark-space gap between the substrate support and the aperture. The aperture may be configured to allow sputter deposition or plasma processing of a site-isolated region on the substrate.

The process chamber may further include a plasma confinement ring between the substrate support and the grounded shield. The plasma confinement ring may be thicker than the substrate. The plasma confinement ring fills the dark-space gap between the substrate support and the grounded shield.

The process chamber may further include a dielectric material in the dark-space gap. The dielectric material may be coated with a metal layer for grounding and RF shielding. The dark-space gap may be between about 1 mm and about 3 mm.

The process chamber may further include a controller to selectively apply power to the one or more sputter guns from the power source and apply power to bias the substrate support from a power source. The controller may be configured to control the power source to perform one or both of plasma processing and PVD deposition on a site-isolated region on the substrate. In some embodiments, other sputter mechanisms can be used instead of the sputter guns.

In some embodiments, a method of combinatorial processing of a substrate is provided in which site-isolated sputter deposition and plasma processing are performed in the same process chamber. The site-isolated sputter deposition may include site-isolated co-sputtering deposition. Cleaning, site-isolated sputter deposition, and plasma processing may be performed in the same process chamber. Cleaning, site-isolated sputter deposition, and plasma processing, and full wafer sputter deposition may be performed in the same process chamber.

In some embodiments, a method of combinatorial processing of a substrate is provided in which sputter deposition and plasma processing are performed in the same process chamber. The sputter deposition may include co-sputtering deposition. Cleaning, sputter deposition, and plasma processing may be performed in the same process chamber. The sputter deposition may result in a gradient in material properties across the length and/or width of the substrate. Physical methods such as scribing or lithography may be used to define the SIRs after the deposition.

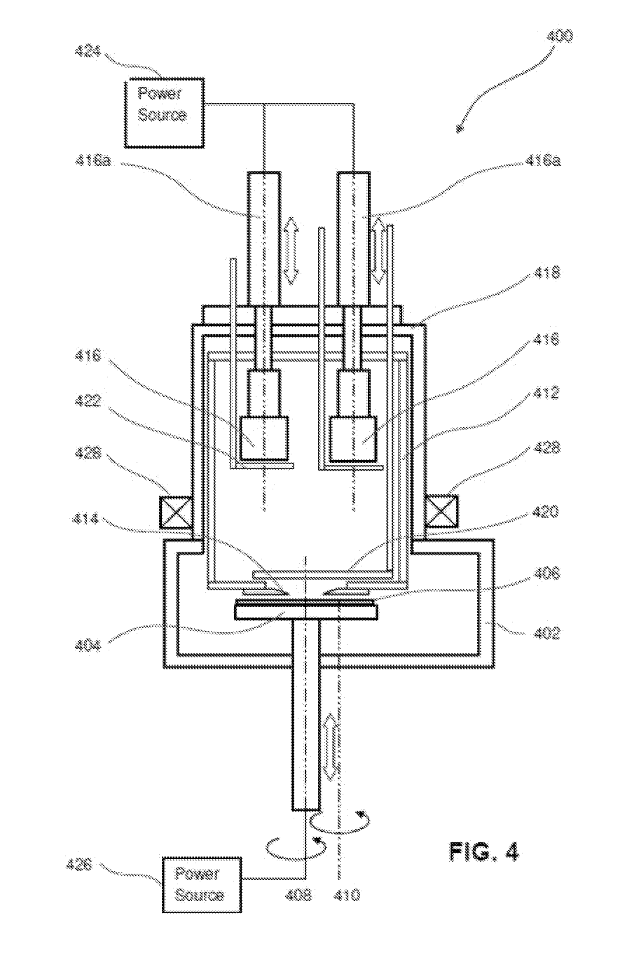

FIG. 4 is a simplified schematic diagram illustrating an exemplary process chamber 400 configured to perform combinatorial processing and full substrate processing in accordance with some embodiments. It will be appreciated that the processing chamber shown in FIG. 4 is merely exemplary and that other process or deposition chambers may be used. Further details on exemplary deposition chambers that can be used can be found in U.S. patent application Ser. No. 11/965,689, now U.S. Pat. No. 8,039,052, filed Dec. 27, 2007, and claiming priority to U.S. Provisional Application No. 60/970,500 filed on Sep. 6, 2007, and U.S. patent application Ser. No. 12/027,980, filed Feb. 7, 2008 and claiming priority to U.S. Provisional Application No. 60/969,955 filed on Sep. 5, 2007, the entireties of which are hereby incorporated by reference.

The processing chamber 400 includes a bottom chamber portion 402 disposed under a top chamber portion 418. A substrate support 404 is provided within the bottom chamber portion 402. The substrate support 404 is configured to hold a substrate 406 disposed thereon and can be any known substrate support, including but not limited to a vacuum chuck, electrostatic chuck or other known mechanisms.

The substrate 406 may be a conventional 200 mm and 300 mm substrate, or any other larger or smaller size. In some embodiments, substrate 406 may be a square, rectangular, or other shaped substrate. The substrate 406 may be a blanket substrate, a coupon (e.g., partial substrate), or even a patterned substrate having predefined regions. In some embodiments, substrate 406 may have regions defined through site-isolated processing as described herein.

The top chamber portion 418 of the chamber 400 includes a process kit shield 412, which defines a confinement region over a portion of the substrate 406. As shown in FIG. 4, the process kit shield 412 includes a sleeve having a base (optionally integrated with the shield) and an optional top. It will be appreciated, however, that the process kit shield 412 may have other configurations. The process kit shield 412 is configured to confine plasma generated in the chamber 400 by sputter guns 416. The positively-charged ions in the plasma strike a target and dislodge atoms from the target. The sputtered neutrals are deposited on an exposed surface of substrate 406. In some embodiments, the process kit shield 412 may be partially moved in and out of chamber 400, and, in other embodiments, the process kit shield 412 remains in the chamber for both full substrate and combinatorial processing. When used in the full substrate configuration, a gradient in the material properties can be introduced across the length and/or width of the substrate.

The base of process kit shield 412 includes an aperture 414 through which a surface of substrate 406 is exposed for deposition processing. The chamber may also include an aperture shutter 420 which is moveably disposed over the base of process kit shield 412. The aperture shutter 420 slides across a bottom surface of the base of process kit shield 412 in order to cover or expose aperture 414. In some embodiments, the aperture shutter 420 is controlled by an arm extension (not shown) which moves the aperture shutter to expose or cover aperture 414.

As shown in FIG. 4, the chamber 400 includes two sputter guns 416. While two sputter guns are illustrated, any number of sputter guns may be included, e.g., one, three, four or more sputter guns may be included. Where more than one sputter gun is included, the plurality of sputter guns may be referred to as a cluster of sputter guns.

The sputter guns 416 are moveable in a vertical direction so that one or both of the guns may be lifted from the slots of the shield. In some embodiments, sputter guns 416 are oriented or angled so that a normal reference line extending from a planar surface of the target of the process gun is directed toward an outer periphery of the substrate in order to achieve good uniformity for full substrate deposition film. The target/gun tilt angle depends on the target size, target-to-substrate spacing, target material, process power/pressure, etc. and the tilt angle may be varied.

The chamber may also include a gun shutter 422, which seals off the sputter gun 416 when it is not needed during processing. The gun shutter 422 allows one or more of the sputter guns 416 to be isolated from certain processes as needed. It will be appreciated that the gun shutter 422 may be integrated with the top of the process kit shield 412 to cover the opening as the process gun 416 is lifted or individual gun shutter 422 can be used for each process gun 416.

The sputter guns 416 may be fixed to arm extensions 416a to vertically move sputter guns 416 toward or away from top chamber portion 418. The arm extensions 416a may be attached to a drive, e.g., lead screw, worm gear, etc. The arm extensions 416a may be pivotally affixed to sputter guns 416 to enable the sputter guns to tilt relative to a vertical axis. In some embodiments, sputter guns 416 tilt toward aperture 414 when performing combinatorial processing and tilt toward a periphery of the substrate being processed when performing full substrate processing. It will be appreciated that sputter guns 416 may alternatively tilt away from aperture 414.

The chamber 400 also includes power sources 424 and 426. Power source 424 provides power for sputter guns 416, and power source 426 provides RF power to bias the substrate support 404. In some embodiments, the output of the power source 426 is synchronized with the output of power source 424. The power source, 424, may output a direct current (DC) power supply, a direct current (DC) pulsed power supply, a radio frequency (RF) power supply or a DC- RF imposed power supply. The power sources 424 and 426 may be controlled by a controller (not shown) so that both deposition and etch can be performed in the chamber 400, as will be described in further detail hereinafter.

The chamber 400 may also include an auxiliary magnet 428 disposed around an external periphery of the chamber 400. The auxiliary magnet 428 is located between the bottom surface of sputter guns 416 and proximity of a substrate support 404. The auxiliary magnet may be positioned proximate to the substrate support 404, or, alternatively, integrated within the substrate support 404. The magnet 428 may be a permanent magnet or an electromagnet. In some embodiments, the auxiliary magnet 428 improves ion guidance as the magnetic field above substrate 406 is re-distributed or optimized to guide the metal ions. In some other embodiments, the auxiliary magnet 428 provides more uniform bombardment of ions and electrons to the substrate and improves the uniformity of the film being deposited.

The substrate support 404 is capable of both rotating around its own central axis 408 (referred to as “rotation” axis), and rotating around an exterior axis 410 (referred to as “revolution” axis). Such dual rotary substrate supports can be advantageous for combinatorial processing using site-isolated mechanisms. Other substrate supports, such as an XY table, can also be used for site-isolated deposition. In addition, substrate support 404 may move in a vertical direction. It will be appreciated that the rotation and movement in the vertical direction may be achieved through one or more known drive mechanisms, including, for example, magnetic drives, linear drives, worm screws, lead screws, differentially pumped rotary feeds, and the like.

Through the rotational movement of the process kit shield 412 and the corresponding aperture 414 in the base of the process kit shield, in combination with the rotational movement of substrate support 404, any region of a substrate 406 may be accessed for combinatorial processing. The dual rotary substrate support 404 allows any region (i.e., location or site) of the substrate 406 to be placed under the aperture 414; hence, site-isolated processing is possible at any location on the substrate 406. It will be appreciated that removal of the aperture 414 and aperture shutter 420 from the chamber 400 or away from the substrate 406 and enlarging the bottom opening of the process kit shield 412 allows for processing of the full substrate.

As described above, embodiments of the invention allow for both sputter deposition and plasma etch to be performed in the same process chamber (e.g., chamber 400). In some embodiments of the invention, the chamber 400 is configured so that both sputter deposition and plasma etch can be performed in the chamber 400, and, in particular, the chamber 400 is configured to allow for both site-isolated sputter deposition and plasma etch to be performed in the chamber. It will be appreciated that full wafer sputter deposition and plasma etch may also be performed in the chamber 400 by removing the aperture 414 away from the chamber 400 or moving the aperture 414 away from the substrate 406 and enlarging the bottom opening of the process kit shield 412.

In particular, plasma etch may be performed in the chamber 400 by applying RF power from the power source 426 to bias the substrate support (e.g., an electrostatic chuck) 404 with or without DC plasma near the sputter target. Plasma is then ignited on top of the substrate 406, which is confined by the aperture 414 and shield 412 above the substrate 406 so that site-isolated plasma etch of the substrate 406 can occur in the chamber 400. Sputter deposition may similarly be performed in the chamber 400 by applying DC power from the power source 424 to the sputter gun(s) 416. Three modes of processing can be performed in chamber 400: sputter deposition only, simultaneous sputter deposition and plasma etch, or plasma etch only.

In some embodiments, the RF power is any value or range of values between about 50 W and about 2000 W. In some embodiments, DC or pulsed DC power applied to sputter sources can have peak powers as high as 10 kW, for example, for high metal ionization in sputter deposition. The RF power frequency may be any value or range of values between about 40 kHz and about 60 MHz. It will be appreciated that the RF power frequency may be less than about 40 kHz or greater than about 60 MHz.

In chamber 400, plasma etch can be used to clean the substrate 406. An exemplary process according to some embodiments of the invention may begin by cleaning the substrate, performing site-isolated sputter deposition, performing site-isolated plasma etch, performing full substrate sputter deposition and then performing a subsequent full substrate plasma etch, all within the same chamber (e.g., chamber 400). Another exemplary process according to some embodiments of the invention may begin by cleaning the substrate, performing a full substrate sputter deposition, performing site-isolated sputter deposition, performing site-isolated plasma etch, performing full substrate sputter deposition, and performing a subsequent full substrate plasma etch, all within the same chamber (e.g., chamber 400). It will be appreciated that the above processes are merely exemplary and that processes according to the invention may include fewer steps or additional steps and that the order of the steps may vary.

In some embodiments, methods, and coated panels fabricated from the methods, are disclosed to include low emissivity coatings that can provide high visible transmission, high light to solar gain, and minimal color change before and after heat treatments. The low emissivity coatings can include one or more infrared reflective layers to increase the light to solar gain property. The low emissivity coatings can include material and thickness optimization to increase the visible transmission property. Further, the low emissivity coatings can include a silicate material doped with rare earth elements.

In some embodiments, methods and apparatus for making coated panels are disclosed. The coated panels can include coated layers formed thereon, such as one or more low resistivity thin infrared reflective layers having a conductive material such as silver. The infrared reflective layer(s) can include a conductive material, with the percentage of reflectance proportional to the conductivity. Thus, a metallic layer, for example silver, can be used as infrared reflective layer(s) in low emissivity coatings. To maintain the conductivity of the infrared reflective layer against oxidation from deposition of subsequent layers or from subsequent high temperature anneals, a barrier layer can be formed on the infrared reflective layer.

In some embodiments, improved coated transparent panels, such as a coated glass, that has acceptable visible light transmission and IR reflection are disclosed. Methods of producing the improved coated transparent panels, which include specific layers in a coating stack, are also disclosed.

The coated transparent panels can include a glass substrate or any other transparent substrates, such as substrates made of organic polymers. The coated transparent panels can be used in window applications such as vehicle and building windows, skylights, or glass doors, either in monolithic glazings or multiple glazings, with or without a plastic interlayer or a gas-filled sealed interspace.

In some embodiments, methods and apparatus for making coated panels are disclosed. The coated panels can include coated layers formed thereon, such as one or more layers that include silicate materials doped with one or more rare earth elements. The rare earth elements include the fifteen lanthanide elements (i.e. Ce, Pr, Nd, Pm, Sm, Eu, Gd, Tb, Dy, Ho, Er, Tm, Yb, Lu) as well as Sc and Y. The rare earth-doped silicate layers may have a thickness between about 100 nanometers (nm) and about 1 micrometer (um). A concentration of the dopant within the rare earth-doped silicate layers may be between about 30 atomic % and about 70 atomic %, such as about 50 atomic %.

Typically, ordinary architectural glass is opaque to the UV portion of the spectrum. Therefore, the UV photons incident on the glass are absorbed in the bulk of the glass substrate and do not participate in either the transmissivity or the IR emissivity of the low-e panel. Rare earth-doped silicate materials absorb photons in the UV portion of the spectrum and emit photons with longer wavelengths (i.e. lower energies). In some embodiments, this emission is within the visible (e.g. wavelengths between 400 nm and 700 nm) portion of the spectrum through phosphorescence. As an example, silicate materials doped with Tb or Dy emit photons only within the visible portion of the spectrum. This property effectively converts the UV photons to visible photons and increases the amount of visible light incident on the front surface of the glass.

Those skilled in the art will understand that the rare earth-doped silicate materials are able to absorb the UV photons and enter an excited state. Energy of the excited state can be lost to the matrix through non-radiative relaxation mechanisms (e.g. vibrational relaxation). Subsequently, the material may emit a photon having a longer wavelength (e.g. lower energy) and return to the ground state. In some embodiments, the emitted photon is within the visible portion of the spectrum. In this way, the coupling between the transmissivity and the IR emissivity can be partially reduced.

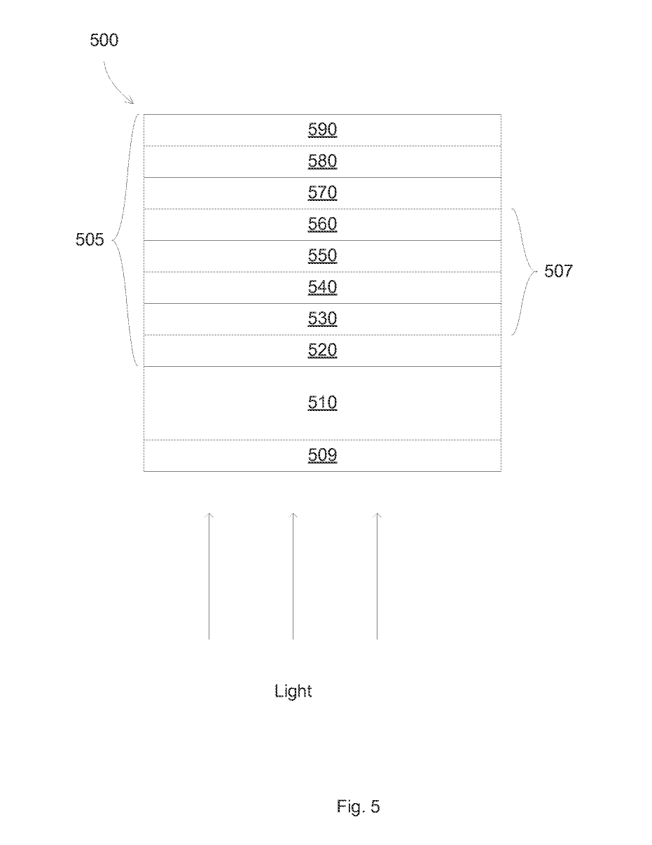

FIG. 5 illustrates a low emissivity transparent panel 500 according to some embodiments. The low emissivity transparent panel can include a glass substrate 510, rare earth-doped silicate layer formed above a first side of the substrate, and a low emissivity (low-e) stack 505 formed above a second side of the glass substrate 510. Those skilled in the art will understand that the light is incident on the first side of the substrate. In some embodiments, the glass substrate 510 is made of a glass, such as borosilicate glass, and has a thickness of, for example, between 1 and 10 millimeters (mm). The substrate 510 may be square or rectangular and about 0.5-2 meters (m) across. In some embodiments, the substrate 510 may be made of, for example, plastic, polycarbonate, or other transparent polymer.

In some embodiments, the rare earth-doped silicate layer 509 is formed on the first side of the substrate. The rare earth-doped silicate layer may be formed using wet deposition techniques. Suitable wet deposition techniques include slurries, inks, pastes, sol-gels, and the like. The rare earth-doped silicate layer may be formed using dry deposition techniques. Suitable dry deposition techniques include physical vapor deposition (PVD), evaporation, pulsed laser deposition (PLD), chemical vapor deposition (CVD), plasma enhanced chemical vapor deposition (PECVD), atomic layer deposition (ALD), plasma enhanced atomic layer deposition (PEALD), and the like.

In some embodiments, the rare earth-doped silicate layer 509 may include one or more rare earth elements (the group defined as the fifteen lanthanide elements Ce, Pr, Nd, Pm, Sm, Eu, Gd, Tb, Dy, Ho, Er, Tm, Yb, and Lu as well as Sc and Y). The rare earth-doped silicate layer 509 may have a thickness between about 100 nm and about 1 um. A concentration of the dopant within the rare earth-doped silicate layers may be between about 30 atomic % and about 70 atomic %, such as about 50 atomic %. In some embodiments, the rare earth-doped silicate layer 509 may include one or more of TB or Dy.

Those skilled in the art will understand that the rare earth-doped silicate layer 509 may be covered with a protective coating (not shown) to protect the layer and give the low-e panel stability. The protective coating will be transparent in both the UV portion as well as the visible portion of the spectrum. Examples of protective coating include silicon nitride and some metal nitride materials, and some metal oxide materials.

In some embodiments, HPC techniques can be used to screen, investigate, and improve the performance of the rare earth-doped silicate layer as discussed previously. Parameters that can be varied in a combinatorial manner include one or more of process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It will be appreciated that these process parameters are exemplary and not meant to be an exhaustive list as other process parameters commonly used in the deposition of the rare earth-doped silicate layer may be varied.

The low-e stack 505 formed on the second side (i.e. opposite side) of the substrate can include a lower protective layer 520, an infrared reflective stack 507, an upper oxide 570, an optical filler layer 580, and an upper protective layer 590. The infrared reflective stack 507 can include a base oxide layer 530, a seed layer 540, a reflective layer 550, and a barrier layer 560. The infrared reflective stack 507 can be repeated for multiple reflective layer applications such as “double-silver (e.g. two reflective stacks)” or “triple silver (e.g. three reflective stacks)” low-e stacks. Some layers can be optional, and other layers can be added, such as interface layers or adhesion layers. Exemplary details as to the functionality provided by each of the layers 520-590 are provided below.

The various layers in the low-e stack 505 may be formed sequentially (i.e., from bottom to top) on the substrate 510 using a physical vapor deposition (PVD) and/or reactive (or plasma enhanced) sputtering processing tool. For example, the layers can be sputtered deposited using different processes and equipment, for example, the targets can be sputtered under direct current (DC), pulsed DC, alternate current (AC), radio frequency (RF) or any other suitable conditions. In some embodiments, the low-e stack 505 is formed over the entire second side of the glass substrate 510. However, in some embodiments, the low-e stack 505 may only be formed on isolated portions of the substrate 110.

The lower protective layer 520 is formed on the surface of the second side of the glass substrate 510. The lower protective layer 520 can include silicon nitride, silicon oxynitride, or other nitride material such as silicon zirconium nitride, to protect the other layers in the stack 505 from diffusion of contaminants from the substrate 510 or to improve the haze reduction properties. In some embodiments, the lower protective layer 520 is made of silicon nitride and has a thickness of, for example, between about 10 nm to 50 nm, such as 25 nm.

The base oxide layer 530 is formed above the lower protective layer 520 and above the substrate 510. The base oxide layer is preferably a metal or metal alloy oxide layer and can serve as an antireflective layer. The base oxide layer 530 may enhance the crystallinity of the reflective layer 550, for example, by enhancing the crystallinity of a seed layer 540 for the reflective layer 550, as is described in greater detail below.

The seed layer 540 can be used to provide a seed layer for the IR reflective layer. For example, a zinc oxide layer deposited before the deposition of a silver reflective layer can provide a silver layer with lower resistivity, which can improve its reflective characteristics.

In some embodiments, the seed layer 540 can be made of a metal oxide, such as zinc oxide, and has a thickness of, for example, 50 Å or less. Generally, seed layers are relatively thin layers of materials formed on a surface (e.g., a substrate) to promote a particular characteristic of a subsequent layer formed over the surface (e.g., on the seed layer). For example, seed layers may be used to affect the crystalline structure (or crystallographic orientation) of the subsequent layer, which is sometimes referred to as “templating.” More particularly, the interaction of the material of the subsequent layer with the crystalline structure of the seed layer causes the crystalline structure of the subsequent layer to be formed in a particular orientation.

For example, a seed layer is used to promote growth of the reflective layer in a particular crystallographic orientation. In some embodiments, the seed layer is a material with a crystal structure/orientation which promotes growth of the reflective layer in the (111) orientation when the reflective layer has a face centered cubic crystal structure (e.g., silver), which is preferable for low-e panel applications.

In some embodiments, the crystallographic orientation can be characterized by X-ray diffraction (XRD) technique, which is based on observing the scattered intensity of an X-ray beam incident upon the layer, (e.g., the silver layer or seed layer), as a function of the scattered angles.

In some embodiments, the term “silver layer having (111) crystallographic orientation”, is understood to mean that there is a (111) crystallographic orientation for the silver layer. The crystallographic orientation can be determined by observing pronounced crystallography peaks in an XRD characterization.

In some embodiments, the seed layer 540 can be continuous and covers the entire substrate. Alternatively, the seed layer 540 may not be formed in a completely continuous manner. The seed layer can be distributed across the substrate surface such that each of the seed layer areas is laterally spaced apart from the other seed layer areas across the substrate surface and do not completely cover the substrate surface. For example, the thickness of the seed layer 540 can be a monolayer or less, such as between 2.0 and 4.0 Å, and the separation between the layer sections may be the result of forming such a thin seed layer (i.e., such a thin layer may not form a continuous layer).

The IR reflective layer 550 is formed above the seed layer 540. The IR reflective layer can be a metallic, reflective film, such as silver, gold, or copper. In general, the IR reflective layer includes a good electrical conductor, blocking the passage of thermal energy. In some embodiments, the IR reflective layer 550 is made of silver and has a thickness of between about 7 nm to about 20 nm. Because the IR reflective layer 550 is formed on the seed layer 540, the growth of the silver IR reflective layer 550 in a (111) crystalline orientation is promoted (e.g. due to the crystallographic orientation of the seed layer 540), which offers low sheet resistance, leading to low panel emissivity.

Because of the promoted (111) textured orientation of the IR reflective layer 550, the conductivity and emissivity of the IR reflective layer 550 is improved. As a result, a thinner reflective layer 550 may be formed that still provides sufficient reflective properties and visible light transmission. Additionally, the reduced thickness of the IR reflective layer 550 allows for less material to be used in each panel that is manufactured, thus improving manufacturing throughput and efficiency, increasing the usable life of the target (e.g., silver) used to form the reflective layer 550, and reducing overall manufacturing costs.

Further, the seed layer 540 can provide a barrier between the base oxide layer 530 and the IR reflective layer 550 to reduce the likelihood of any reaction of the material of the reflective layer 550 and the oxygen in the base oxide layer 530, especially during subsequent heating processes. As a result, the resistivity of the reflective layer 550 may be reduced, thus increasing performance of the reflective layer 550 by lowering the emissivity.

In some embodiments, barrier layers can be formed on an infrared reflective layer to protect the infrared reflective layer from impurity diffusion, together with exhibiting good adhesion and good optical properties, for example, during the fabrication process.

The barrier layer 560 is formed above the IR reflective layer 550. The barrier layer 560 can include at least one of nickel, niobium, titanium, aluminum, or chromium, and oxygen. The silver layer should be as pure as possible to maintain its low emissivity performance. The layer immediately on top of the silver layer (e.g., the barrier layer) can be important in protecting the silver from oxidation, such as during oxygen reactive sputtering processes in the deposition of subsequent layers. In addition, this barrier layer can protect the silver layer against reaction with oxygen diffusion during the glass tempering process, or during long term use where the panel may be exposed to moisture or the environment.

In addition to the oxygen diffusion barrier property, there are other desirable properties for the barrier layer. For example, since the barrier layer is placed directly on the silver layer, low or no solubility of the barrier material in silver is desirable to minimize reactivity between the barrier layer and silver at the interface. The reaction between the barrier layer and silver can introduce impurities in the silver layer, potentially reducing the conductivity.

Upper oxide layer 570 is formed above the barrier layer 560 which can function as an antireflective film stack, including a single layer or multiple layers having different functional purposes. The upper oxide layer 570 can serve to reduce the reflection of visible light. The upper oxide layer 570 can be selected based on transmittance, index of refraction, adherence, chemical durability, and thermal stability. In some embodiments, the upper oxide layer 570 includes zinc tin oxide (ZnSnO), offering high thermal stability properties. The upper oxide layer 570 can also include titanium dioxide, silicon nitride, silicon dioxide, silicon oxynitride, niobium oxide, silicon zirconium nitride, tin oxide, zinc oxide, or any other suitable dielectric material.

The optical filler layer 580 can be used to provide a proper thickness to the low-e stack, (e.g. to provide an antireflective property). The optical filler layer preferably has high visible light transmittance. In some embodiments, the optical filler layer 580 is made of tin oxide or zinc oxide and has a thickness of, for example, between 3 nm and 60 nm, such as between 3 nm and 20 nm. In some embodiments, the optical filler layer 580 is made of zinc tin oxide (ZnSnO) and has a thickness of, for example between 3 nm and 60 nm, such as between 3 nm and 20 nm. The optical filler layer may be used to tune the optical properties of the low-e panel 500. For example, the thickness and refractive index of the optical filler layer may be used to increase the layer thickness to a multiple of the incoming light wavelengths, effectively reducing the light reflectance and improving the light transmittance.

An upper protective layer 590 is formed above the optical filler layer 180 and can be used for protecting the total film stack, to protect the panel from physical or chemical abrasion. The upper protective layer 590 can be an exterior protective layer, such as silicon nitride, silicon oxynitride, titanium oxide, tin oxide, zinc oxide, niobium oxide, or silicon zirconium nitride.

In some embodiments, adhesion layers can be used to provide adhesion between layers. The adhesion layers can be made of a metal alloy, such as nickel-titanium, and have a thickness of, for example, 30 Å.

Depending on the materials used, some of the layers of the low-e stack 505 may have some elements in common. An example of such a stack may use a zinc-based material in the oxide dielectric layers 530 and 570. As a result, a relatively low number of different sputtering targets can be used for the formation of the low-e stack 505.

Further, in the fabrication of low emissivity coated panels, high temperature processes can be used to anneal the deposited films or to temper the substrate. The high temperature processes can have adverse effects on the low emissivity coating, such as changing the structure or the optical properties, (e.g., index of refraction n or absorption coefficient k), of the coated films. Thus thermal stability with respect to optical properties is desirable.

In some embodiments, the coating can include multiple infrared reflective stacks 507, such as a double or triple infrared reflective stacks with two or three infrared reflective silver layers.

In some embodiments, the effects of the deposition process of the layers deposited above the silver IR reflective layer on the quality of the silver IR reflective layer are disclosed. Since the silver IR reflective layer is desirably thin, (e.g. less than 20 nm, to provide high visible light transmission), the quality of the silver IR reflective layer can be affected by the deposition of the subsequently deposited layers, such as the barrier layer or the antireflective layer.

In some embodiments, sputter deposition processes, which can be applied for a rare earth-doped silicate layer deposited on a first side of a substrate, are disclosed. For example, the rare earth-doped silicate layer can serve to absorb UV photons incident on the first side of the substrate and emit visible photons through a phosphorescence process. In some embodiments, the rare earth-doped silicate layer can be sputtered from an alloyed target, or co-sputtered from different elemental targets onto the substrate.

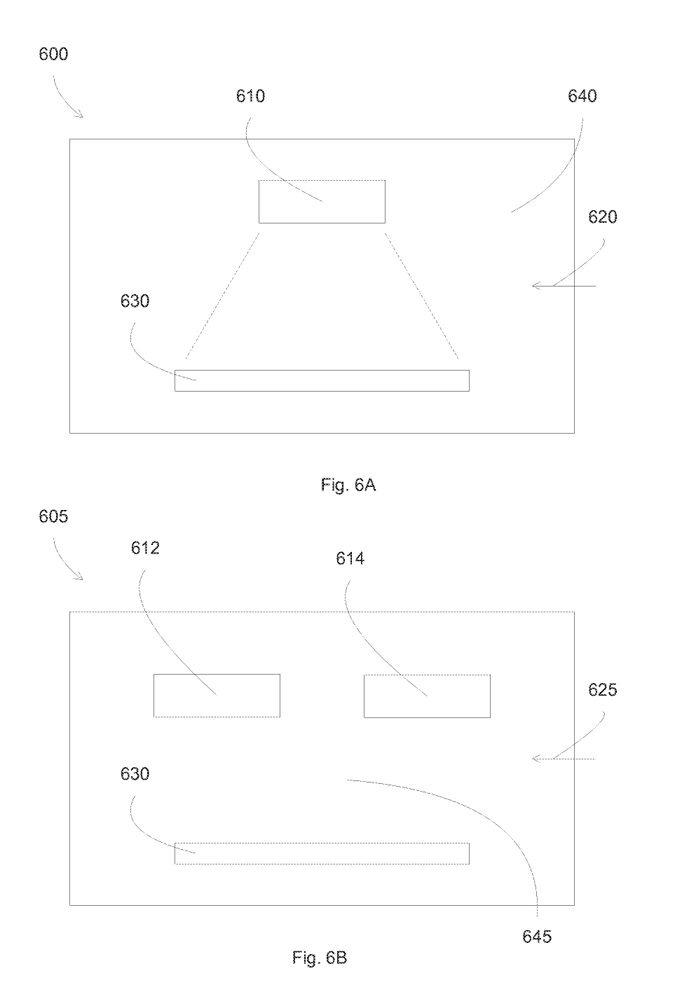

FIGS. 6A-6B illustrate physical vapor deposition (PVD) systems according to some embodiments. In FIG. 6A, a PVD system, also commonly called sputter system or sputter deposition system, 600 includes a housing that defines, or encloses, a processing chamber 640, a substrate 630, a target assembly 610, and reactive species delivered from an outside source through a gas inlet 620. During deposition, the target is bombarded with argon ions, which releases sputtered particles toward the substrate 630. The sputter system 600 can perform blanket deposition on the substrate 630, forming a deposited layer that covers the whole substrate, (e.g., the area of the substrate that can be reached by the sputtered particles generated from the target assembly 610).

The materials used in the target of target assembly 610 may include silicates and/or rare earth compounds for the rare earth-doped silicate layers, zinc for the seed layer, silver for the IR reflective layer, and other metals for other layers. Additionally, the materials used in the targets may include oxygen, nitrogen, or a combination of oxygen and nitrogen in order to form the oxides, nitrides, and oxynitrides of the metals described above. The different targets can be used to deposit different layers in the low-e coating stack, in addition to the metal alloy seed layer. Additionally, although only one target assembly 610 is shown, additional target assemblies may be used. As such, different combinations of targets may be used to form the dielectric layers described above. For example, in some embodiments in which the dielectric material is zinc-tin-oxide, the zinc and the tin may be provided by separate zinc and tin targets, or they may be provided by a single zinc-tin alloy target. A target assembly 610 can include a silver target to sputter deposit a silver layer on substrate 630. The target assembly 610 can include a metal or metal alloy target, and together with reactive species of oxygen and/or nitrogen to sputter deposit a metal alloy oxide layer, a metal alloy nitride layer, or a metal alloy oxynitride layer.

The sputter deposition system 600 can include other components, such as a substrate support for supporting the substrate. The substrate support can include a vacuum chuck, electrostatic chuck, or other known mechanisms. The substrate support can be capable of rotating around an axis thereof that is perpendicular to the surface of the substrate. In addition, the substrate support may move in a vertical direction or in a planar direction. It should be appreciated that the rotation and movement in the vertical direction or planar direction may be achieved through known drive mechanisms which include magnetic drives, linear drives, worm screws, lead screws, a differentially pumped rotary feed through drive, etc.

In some embodiments, the substrate support includes an electrode which is connected to a power supply to provide a RF or DC bias to the substrate, or to provide a plasma environment in the processing chamber 640. The target assembly 610 can include an electrode which is connected to a power supply to generate a plasma in the process housing. The target assembly 610 is preferably oriented towards the substrate 630.

The sputter deposition system 600 can also include a power supply coupled to the target electrode. The power supply provides power to the electrodes, causing material to be sputtered from the target. During sputtering, inert gases, such as argon or krypton, may be introduced into the processing chamber 640 through the gas inlet 620. In embodiments in which reactive sputtering is used, reactive gases may also be introduced, such as oxygen and/or nitrogen, which interact with particles ejected from the targets to form oxides, nitrides, and/or oxynitrides on the substrate.

The sputter deposition system 600 can also include a control system (not shown) having a processor and a memory, which is in operable communication with the other components and configured to control the operation thereof in order to perform the methods described herein.

FIG. 6B shows a sputter system having co-sputtering targets according to some embodiments. A sputter deposition chamber 605 can include two target assemblies 612 and 614 (or other numbers of targets) disposed in a plasma environment 645, containing reactive species delivered from an outside source 625. For example, the target assemblies 612 and 614 can include the metal elements of the metal alloy seed oxide layer, (e.g., nickel, titanium, and niobium) to deposit an alloy of nickel-titanium-niobium on substrate 630. This configuration serves as an example, and other sputter system configurations can be used, such as a single target having an alloy material.

In some embodiments, methods and apparatus for making low emissivity panels, including forming an IR reflective layer formed over a metal alloy seed layer that includes an alloy of nickel titanium and niobium are disclosed. The panels can exhibit improved IR reflectance, improved color neutrality, thermal stability, and durability due to the metal alloy seed layer templating the IR reflective layer while not degrading the low emissivity coating characteristics.

In some embodiments, methods for making low emissivity panels in large area coaters are disclosed. A transport mechanism can be provided to move a substrate under one or more sputter targets, to deposit a conductive layer underlayer before depositing a barrier layer, an antireflective layer, together with other layers such as a surface protection layer.

In some embodiments, in-line deposition systems, including a transport mechanism for moving substrates between deposition stations are disclosed.

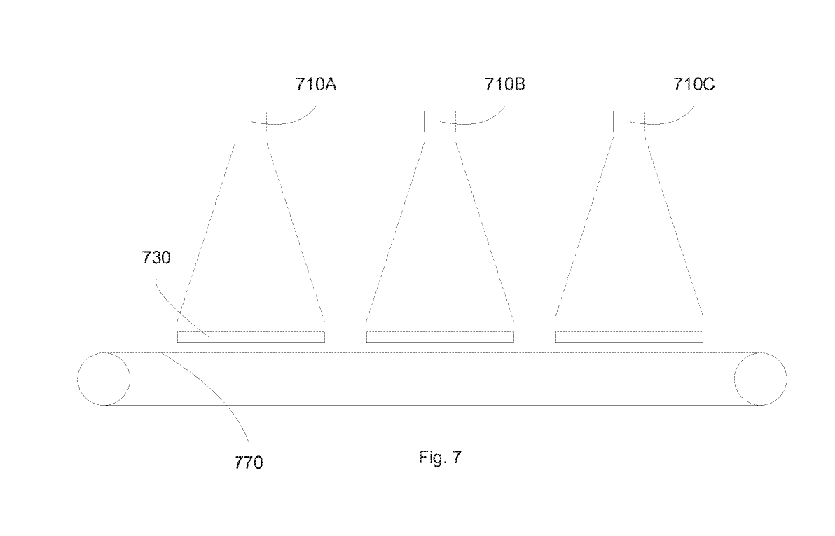

FIG. 7 illustrates an exemplary in-line deposition system according to some embodiments. A transport mechanism 770, such as a conveyor belt or a plurality of rollers, can transfer substrate 730 between different sputter deposition stations. For example, the substrate can be positioned at station #1, having a target assembly 710A, then transferred to station #2, having target assembly 710B, and then transferred to station #3, having target assembly 710C. The station #1 having target assembly 710A can be a metal alloy seed layer deposition station, sputtering a metal alloy seed layer including nickel, titanium, and niobium. As shown, the station #1 includes a single target assembly 710A. However, other configurations can be used, such as co-sputtering system utilizing multiple targets. The station #2 having target assembly 710B can be an IR reflective layer deposition station, sputtering a silver layer. The station #3 having target 710C assembly can be used to deposit other layers, such as an barrier layers or antireflective layers or protection layers.

In some embodiments, methods, and coated panels fabricated from the methods, are disclosed to include coatings, (e.g., one or more IR reflective layers), with minimal color change before and after heat treatments. The methods can include forming a rare earth-doped layer on a front side of the coated panels.

In some embodiments, a low emissivity panel is provided, which can have high visible light transmission, high light to solar gain, color neutrality, and small color change after thermal cycles. The low emissivity panels can include coated layers formed thereon, such as one or more layers formed on the front side of the panel that include silicate materials doped with one or more rare earth elements. The rare earth elements include the fifteen lanthanide elements (i.e. Ce, Pr, Nd, Pm, Sm, Eu. Gd, Tb, Dy, Ho, Er, Tm, Yb, Lu) as well as Sc and Y. The rare earth-doped silicate layers may have a thickness between about 100 nanometers (nm) and about 1 micrometer (um). A concentration of the dopant within the rare earth-doped silicate layers may be between about 30 atomic % and about 70 atomic %, such as about 50 atomic %. The low emissivity panel can include a low emissivity stack formed on the backside of the panel. The low emissivity stack can include a lower protection layer, such as silicon nitride, on a glass substrate. The thickness of the silicon nitride can be between 10 and 30 nm. Above the silicon nitride layer is formed an IR reflective stack. The IR reflective stack can include (from top to bottom) a barrier layer, such as NiNbTiOₓ, formed above an IR reflective layer, such as silver, formed above a seed layer, such as ZnO, formed above a base oxide layer, such as ZnSnOₓ. The thickness of the NiNbTiOₓ barrier layer can be between 1 and 5 nm. The thickness of the silver layer can be between 8 and 12 nm. The thickness of the ZnO seed layer can be between 3 and 10 nm. The thickness of the ZnSnO base oxide layer can be between 10 and 40 nm. Additional IR reflective stacks can be formed above the first infrared reflective stack. Above the IR reflective stack(s) is an upper oxide layer, such as ZnSnO. The thickness of the ZnSnO upper oxide layer can be between 10 and 40 nm. Above the upper oxide layer is formed an optical filler layer, such as ZnO. The thickness of the ZnO optical filler layer can be between 3 and 60 nm. Above the optical filler layer is an upper protective layer, such as silicon nitride. The thickness of the silicon nitride upper protective layer can be between 10 and 30 nm.

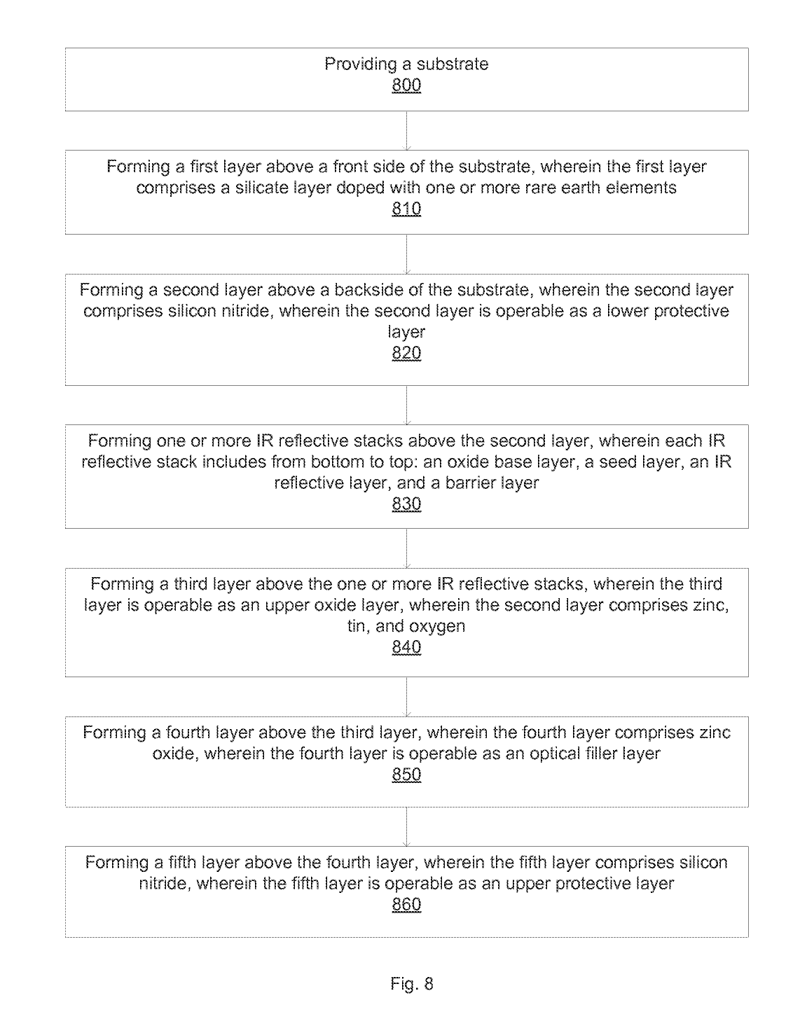

FIG. 8 illustrates a flow chart for sputtering coated layers according to some embodiments. At least one IR reflective stack is formed sequentially on a substrate, together with a one or more layers formed on the front side of the panel that include silicate materials doped with one or more rare earth elements. The rare earth elements include the fifteen lanthanide elements (i.e. Ce, Pr, Nd, Pm, Sm, Eu, Gd, Tb, Dy, Ho, Er, Tm, Yb, Lu) as well as Sc and Y. The rare earth-doped silicate layers may have a thickness between about 100 nanometers (nm) and about 1 micrometer (um). A concentration of the dopant within the rare earth-doped silicate layers may be between about 30 atomic % and about 70 atomic %, such as about 50 atomic %.

In operation 800, a substrate is provided. The substrate can be a transparent substrate, such as a glass substrate, a polymer substrate, or other substrates discussed previously.

In operation 810, a first layer is formed on the front side of the panel that include silicate materials doped with one or more rare earth elements. The rare earth elements include the fifteen lanthanide elements (i.e. Ce, Pr, Nd, Pm, Sm, Eu. Gd, Tb, Dy, Ho, Er, Tm, Yb, Lu) as well as Sc and Y. The rare earth-doped silicate layers may have a thickness between about 100 nanometers (nm) and about 1 micrometer (um). A concentration of the dopant within the rare earth-doped silicate layers may be between about 30 atomic % and about 70 atomic %, such as about 50 atomic %.

In operation 820, a second layer is formed above the back side of the substrate. The second layer can be operable as a lower protective layer. In some embodiments, the second layer can include silicon nitride. The thickness of the second layer can be between about 10 and 30 nm.

In operation 830, one or more infrared reflective stacks are formed above the second layer. Each of the one or more infrared reflective stacks can include (from bottom to top) a base oxide layer, a seed layer, an IR reflective layer, and a barrier layer. In some embodiments, the base oxide layer can include zinc tin oxide. In some embodiments, the seed layer can include zinc oxide. In some embodiments, the IR reflective layer can include silver. In some embodiments, the barrier layer can include NiTiNbO.

In operation 840, a third layer is formed above the one or more infrared reflective stacks. The third layer can be operable as an upper oxide layer. The third layer can include zinc tin oxide. The thickness of the third layer can be between 5 and 100 nm.

In operation 850, a fourth layer is formed above the third layer. The fourth layer can be operable as an optical filler layer. The fourth layer can include zinc oxide. The thickness of the fourth layer can be between 3 and 60 nm.

In operation 860, a fifth layer is formed above the fourth layer. The fifth layer can be operable as an upper protective layer. The fifth layer can include silicon nitride. The thickness of the fifth layer can be between 10 and 30 nm.

Although the foregoing examples have been described in some detail for purposes of clarity of understanding, the invention is not limited to the details provided. There are many alternative ways of implementing the invention. The disclosed examples are illustrative and not restrictive.

What is claimed is:

1. A method for making a coated article, the method comprising:
forming a first layer above a first surface of a substrate, wherein the first layer consists of a rare earth-doped silicate;
forming a second layer above a second surface of the substrate, wherein the second layer comprises silicon nitride, wherein the second layer is operable as a lower protective layer;
forming one or more IR reflective stacks above the second layer, wherein each of the IR reflective stacks comprises a base oxide layer, a seed layer, an IR reflective layer, and a barrier layer;
forming a third layer above the one or more IR reflective stacks, wherein the third layer comprises zinc, tin, and oxygen, wherein the third layer is operable as an upper oxide layer;
forming a fourth layer above the third layer, wherein the fourth layer comprises zinc, and oxygen, wherein the fourth layer is operable as an optical filler layer; and
forming a fifth layer above the fourth layer, wherein the fifth layer comprises silicon nitride, wherein the fifth layer is operable as an upper protective layer.

2. A method as in claim 1 wherein a rare earth dopant in the first layer is at least one of Ce, Pr, Nd, Pm, Sm, Eu, Gd, Tb, Dy, Ho, Er, Tm, Yb, Lu, Sc, or Y.

3. A method as in claim 2 wherein a rare earth dopant in the first layer is at least one of Tb or Dy.

4. A method as in claim 1 wherein the second surface of the substrate is on a side of the substrate opposite the first surface.

5. A method as in claim 4 wherein the first layer is formed directly on the first surface of the substrate.

6. A method as in claim 1 wherein a thickness of the first layer is between 100 nm and 1 um.

7. A method as in claim 1 wherein the first layer is formed by a wet deposition technique or a dry deposition technique.

8. A method as in claim 7 wherein the wet deposition technique comprises one of slurries, inks, pastes, or sol-gel.

9. A method as in claim 7 wherein the dry deposition technique comprises one of physical vapor deposition (PVD), evaporation, pulsed laser deposition (PLD), chemical vapor deposition (CVD), plasma enhanced chemical vapor deposition (PECVD), atomic layer deposition (ALD), plasma enhanced atomic layer deposition (PEALD).

10. A method as in claim 9 wherein the dry deposition technique comprises one of physical vapor deposition (PVD).

11. A method as in claim 1 wherein:
the base oxide layer comprises zinc, tin, and oxygen;
wherein the reflective layer comprises silver; and
wherein the barrier layer comprises nickel, titanium, niobium, and oxygen.

12. A method as in claim 1 further comprising forming a protective layer above the first layer, wherein the protective layer comprises one of silicon nitride, a metal nitride, or a metal oxide.

13. A method as in claim 5 wherein the substrate consists of glass, polyimide, plastic, or polyethylene terephthalate (PET).

14-20. (canceled)

21. A method for making a coated article, the method comprising:
providing a substrate, wherein the substrate comprises a first surface and a second surface, the second surface of the substrate being on a side of the substrate opposite the first surface;
forming a first layer directly on the first surface of the substrate, wherein the first layer consists of a silicate doped with at least one rare earth element;
forming a second layer above the second surface of the substrate, wherein the second layer comprises silicon nitride;
forming one or more IR reflective stacks above the second layer, wherein each of the IR reflective stacks comprises a base oxide layer, a seed layer, an IR reflective layer, and a barrier layer;
forming a third layer above the one or more IR reflective stacks, wherein the third layer comprises zinc, tin, and oxygen;
forming a fourth layer above the third layer, wherein the fourth layer comprises zinc, and oxygen; and
forming a fifth layer above the fourth layer, wherein the fifth layer comprises silicon nitride.

22. A method as in claim 21 wherein the at least one rare earth element comprises at least one of Ce, Pr, Nd, Pm, Sm, Eu, Gd, Tb, Dy, Ho, Er, Tm, Yb, Lu, Sc, or Y.

23. A method as in claim 22 wherein the at least one rare earth element comprises at least one of Tb or Dy.

24. A method as in claim 21 wherein the substrate consists of glass, polyimide, plastic, or polyethylene terephthalate (PET).

25. A method as in claim 21 wherein the second layer is formed directly on the second surface of the substrate.

26. A method as in claim 25 wherein the one or more IR reflective stacks is formed directly on the second layer.
